(19) United States
(12) Patent Application Publication
(10) Pub. No.: US 2025/0071976 A1
(43) Pub. Date: Feb. 27, 2025

(54) SEMICONDUCTOR STRUCTURES AND THEIR FORMATION METHODS

(71) Applicant: CXMT CORPORATION, Hefei (CN)

(72) Inventors: Mengmeng YANG, Hefei (CN); Yi TANG, Hefei (CN)

(21) Appl. No.: 18/946,842

(22) Filed: Nov. 13, 2024

Related U.S. Application Data
(63) Continuation of application No. PCT/CN2023/110951, filed on Aug. 3, 2023.

(30) Foreign Application Priority Data
Jan. 3, 2023 (CN) 202310002798.2

(51) Int. Cl. H10B 12/00

(52) U.S. Cl. CPC H10B 12/482; H10B 12/02

(57) ABSTRACT

A semiconductor structure includes a substrate, a stacked structure, a signal line group, and a first staircase structure. The stacked structure is located on the substrate, and includes multiple storage layers arranged at intervals in a first direction, and each storage layer includes multiple memory cells arranged at intervals in a second direction. The signal line group includes multiple signal lines arranged at intervals in the first direction, and each signal line is electrically connected to the memory cells. The first staircase structure includes first stairs electrically connected to the signal lines, each first stair protrudes from a corresponding signal line in a third direction, and projections of the multiple first stairs on a top surface of the substrate are arranged in the second direction.

### CROSS-REFERENCES TO RELATED APPLICATIONS

This application is a continuation of PCT/CN2023/110951, filed on Aug. 3, 2023, which claims priority to Chinese Patent Application No. 202310002798.2, filed on Jan. 3, 2023, and entitled “SEMICONDUCTOR STRUCTURE AND METHOD FOR FORMING SAME”, the disclosures of which are incorporated herein by reference in their entireties.

### FIELD

The present disclosure relates to the field of semiconductor manufacturing technologies, and in particular, to a semiconductor structure and a method for forming the same.

### BACKGROUND

A dynamic random access memory (DRAM) is a semiconductor device commonly utilized in electronic devices such as computers. The DRAM includes multiple memory cells, and each memory cell generally includes a transistor and a capacitor. The gate of the transistor is electrically connected to a word line, the source is electrically connected to a bit line, and the drain is electrically connected to the capacitor. The voltage on the word line can control the transistor to be turned on or off, allowing data information stored in the capacitor to be read through the bit line, or data information to be written into the capacitor.

To improve a storage capacity and integration of a semiconductor structure such as the DRAM, the semiconductor structure such as the DRAM has been developed from a two-dimensional (2D) structure to a three-dimensional (3D) structure. A first staircase structure can well assist in implementing a 3D process of the semiconductor structure such as the DRAM. However, a current first staircase structure faces significant challenges in terms of an area ratio, a capacitive coupling effect, and the like, which limits further improvement of performance of the semiconductor structure such as the DRAM.

Therefore, how to reduce an overall projection area of the first staircase structure and lower the capacitive coupling effect inside the semiconductor structure, so as to improve the performance of the semiconductor structure is an urgent technical problem to be currently resolved.

### SUMMARY

Some embodiments of the present disclosure provide a semiconductor structure and a method for forming the same.

According to some embodiments, the present disclosure provides a semiconductor structure, including: a substrate; a stacked structure, located on a top surface of the substrate, the stacked structure including multiple storage layers arranged at intervals in a first direction, each one of the multiple storage layers including multiple memory cells arranged at intervals in a second direction, the first direction being perpendicular to the top surface of the substrate, and the second direction being parallel to the top surface of the substrate; a signal line group, including multiple signal lines arranged at intervals in the first direction, each one of the multiple signal lines extending in the second direction and being electrically connected to the multiple memory cells in each of the multiple storage layers; and a first staircase structure, including multiple first stairs electrically connected to the multiple signal lines in a one-to-one correspondence, each one of the multiple first stairs protruding from a corresponding signal line in a third direction, projections of the multiple first stairs on the top surface of the substrate being arranged in the second direction, the third direction being parallel to the top surface of the substrate, and the second direction intersecting the third direction.

According to some other embodiments, the present disclosure further provides a method for forming a semiconductor structure, including the steps as follows. A substrate is provided. A stacked structure is formed on a top surface of the substrate. The stacked structure includes multiple storage layers arranged at intervals in a first direction, and each one of the multiple storage layers includes multiple memory cells arranged at intervals in a second direction. The first direction is perpendicular to the top surface of the substrate, and the second direction is parallel to the top surface of the substrate. A signal line group is formed on the substrate. The signal line group includes multiple signal lines arranged at intervals in the first direction, and each one of the multiple signal lines extends in the second direction and is electrically connected to the multiple memory cells in each one of the multiple storage layers. A first staircase structure is formed on the substrate. The first staircase structure includes multiple first stairs electrically connected to the multiple signal lines in a one-to-one correspondence, each one of the multiple first stairs protrudes from a corresponding signal line in a third direction, and projections of the multiple first stairs on the top surface of the substrate are arranged in the second direction. The third direction is parallel to the top surface of the substrate, and the second direction intersects the third direction.

### BRIEF DESCRIPTION OF THE DRAWINGS

FIG. 1 is a schematic diagram of a semiconductor structure according to some embodiments of the present disclosure;

FIG. 2 is a schematic cross-sectional diagram of a first staircase structure in a semiconductor structure according to some embodiments of the present disclosure;

FIG. 3 is another schematic cross-sectional diagram of a first staircase structure in a semiconductor structure according to some embodiments of the present disclosure;

FIG. 4 is a schematic side view of a semiconductor structure according to some embodiments of the present disclosure;

FIG. 5 is a flowchart of a method for forming a semiconductor structure according to some embodiments of the present disclosure; and

FIG. 6 to FIG. 22 are schematic diagrams of main process structures in a procedure of forming a semiconductor structure according to some embodiments of the present disclosure.

### DETAILED DESCRIPTION OF THE DISCLOSURE

Specific implementations of a semiconductor structure and a method for forming the same provided in the present disclosure are described below in detail with reference to accompanying drawings.

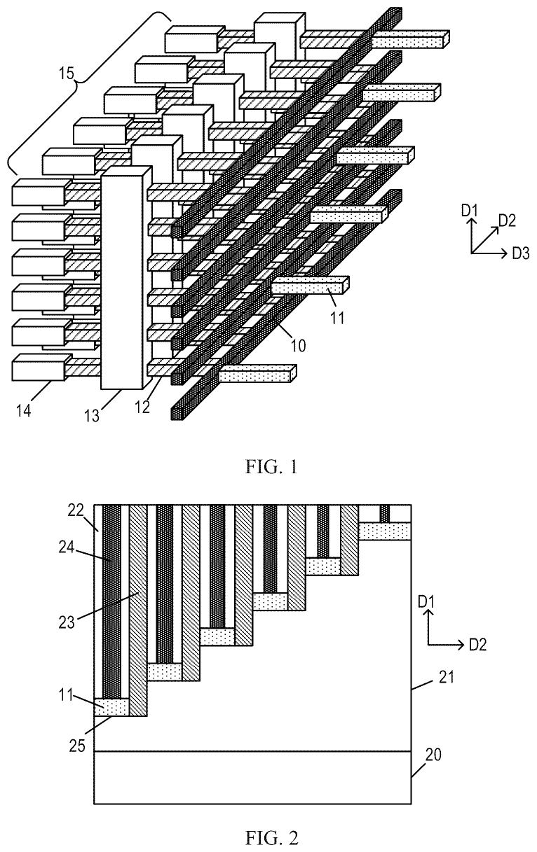

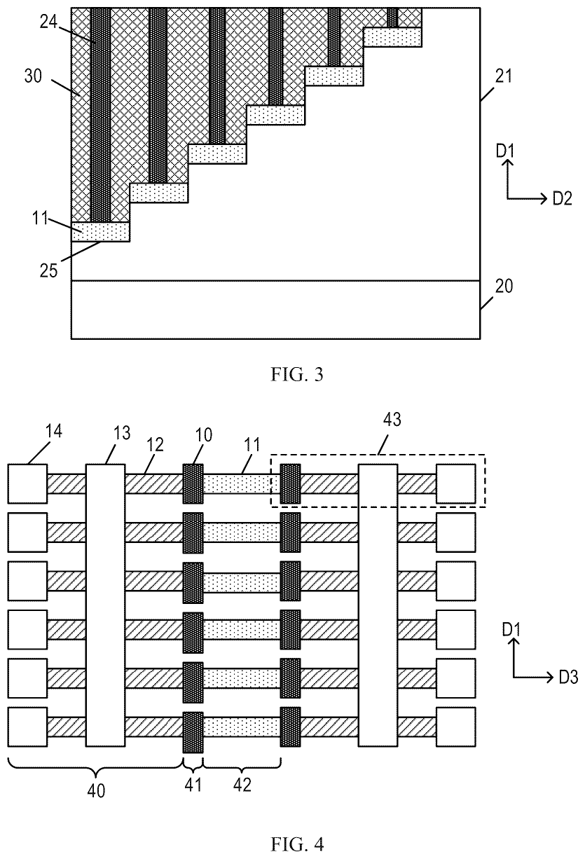

The present disclosure provides a semiconductor structure. FIG. 1 is a schematic diagram of a semiconductor structure according to some embodiments of the present disclosure. FIG. 2 is a schematic cross-sectional diagram of a first staircase structure in a semiconductor structure according to some embodiments of the present disclosure. FIG. 3 is another schematic cross-sectional diagram of a first staircase structure in a semiconductor structure according to some embodiments of the present disclosure. FIG. 4 is a schematic side view of a semiconductor structure according to some embodiments of the present disclosure. As shown in FIG. 1 to FIG. 4, the semiconductor structure includes: a substrate 20; a stacked structure 40, located on a top surface of the substrate 20, the stacked structure 40 including multiple storage layers 15 arranged at intervals in a first direction D1, each one of the multiple storage layers 15 including multiple memory cells 43 arranged at intervals in a second direction D2, the first direction D1 being perpendicular to the top surface of the substrate 20, and the second direction D2 being parallel to the top surface of the substrate 20; a signal line group 41, including multiple signal lines 10 arranged at intervals in the first direction D1, each one of the multiple signal lines 10 extending in the second direction D2 and being electrically connected to the multiple memory cells 43 in each one of the multiple storage layers 15; and a first staircase structure 42, including multiple first stairs 11 electrically connected to the multiple signal lines 10 in a one-to-one correspondence, each one of the multiple first stairs 11 protruding from a corresponding signal line 10 in a third direction D3, projections of the multiple first stairs 11 on the top surface of the substrate 20 being arranged in the second direction D2, the third direction D3 being parallel to the top surface of the substrate 20, and the second direction D2 intersecting the third direction D3. As shown in FIG. 2, the projections of the multiple first stairs 11 on the top surface of the substrate 20 are arranged at intervals in the second direction D2. As shown in FIG. 3, the projections of the multiple first stairs 11 on the top surface of the substrate 20 are arranged in abutment in the second direction D2.

The semiconductor structure in this specific implementation may be but is not limited to a DRAM. In this specific implementation, an example in which the semiconductor structure is a DRAM is utilized for description. For example, the semiconductor structure may be a three-dimensional DRAM structure. The substrate 20 may be but is not limited to a silicon substrate. In some embodiments, an example in which the substrate 20 is a silicon substrate is utilized for description. In another embodiment, the substrate 20 may alternatively be a semiconductor substrate such as gallium nitride, gallium arsenide, gallium carbide, silicon carbide, or silicon-on-insulator (SOI). The substrate 20 is configured to support a device structure above the substrate 20. The top surface of the substrate 20 is a surface that is of the substrate 20 and that faces to the stacked structure 40. Each one of the multiple signal lines 10 may be a word line, a bit line, or another signal transmission line in the DRAM.

For example, each one of the multiple signal lines 10 is a bit line in the DRAM, and the semiconductor structure may include multiple memory cells 43 arranged in an array in the first direction D1 and the second direction D2, to form a memory array. Each one of the multiple memory cells 43 includes a transistor and a capacitor 14. The transistor includes an active pillar 12 extending in the third direction D3, the active pillar 12 includes a channel region, and a source region and a drain region distributed on two opposite sides of the channel region in the third direction D3, and the capacitor 14 is electrically connected to the drain region. The semiconductor structure further includes multiple word lines 13 extending in the first direction D1 and being arranged at intervals in the second direction D2, and each word line 13 is connected to channel regions of multiple memory cells 43 arranged at intervals in the first direction D1. The multiple signal lines 10 (that is, bit lines) extend in the second direction D2 and are arranged at intervals in the first direction D1, and each signal line 10 is electrically connected to source regions of all memory cells 43 in one storage layer 15.

In this specific implementation, the first staircase structure 42 is disposed at an end portion of the signal line group in the third direction D3, the multiple first stairs 11 in the first staircase structure 42 protrude from the signal lines 10 in a one-to-one correspondence in the third direction D3 and are electrically connected to the signal lines 10, and the projections of the multiple first stairs 11 on the top surface of the substrate 20 are arranged in the second direction D2. In this way, not only an overlapping area between two first stairs 11 electrically connected to two adjacent signal lines 10 can be reduced, but also a distance, in each of the first direction D1 and the second direction D2, between the two first stairs 11 electrically connected to the two adjacent signal lines 10 can be increased, thereby lowering a capacitive coupling effect between the adjacent first stairs 11, and improving electrical performance of the semiconductor structure. In addition, in this specific implementation, only the first staircase structure 42 including the multiple first stairs 11 needs to be disposed at the end portion of the signal lines 10 in the third direction D3, and an electrical signal in each one of the multiple signal lines 10 is extracted and/or introduced through each one of the multiple first stairs 11. Therefore, the multiple signal lines 10 can be equal in length in the second direction D2, and there is no need to form a staircase structure including signal lines of different lengths. In this way, a manufacturing process of the semiconductor structure is simplified, manufacturing costs of the semiconductor structure are lowered, and a projection area of each of the first staircase structure and the entire semiconductor structure is reduced, helping further miniaturize the size of the semiconductor structure.

In some embodiments, the semiconductor structure further includes a conductive pillar structure, which includes multiple conductive pillars electrically connected to the multiple first stairs in a one-to-one correspondence, each one of the multiple conductive pillars extends in the first direction D1 and is located above a corresponding first stair, and the conductive pillar structure is configured to extract and/or introduce an electrical signal in each one of the multiple signal lines through each one of the multiple first stairs. The multiple conductive pillars may have the same size in the second direction D2 and may be evenly arranged at intervals in the second direction D2, and the heights, in the first direction D1, of the multiple conductive pillars evenly arranged at intervals in the second direction D2 may increase or decrease in sequence.

In some embodiments, the semiconductor structure further includes a conductive pillar structure, which includes multiple conductive pillars 24 electrically connected to the multiple first stairs 11 in a one-to-one correspondence, each one of the multiple conductive pillars 24 extends in the first direction D1 and is located above a corresponding first stair 11, and in any two of the multiple conductive pillars 24, the width, in the second direction D2, of a conductive pillar 24 electrically connected to a first stair 11 closer to the substrate 20 is greater than the width, in the second direction D2, of a conductive pillar 24 electrically connected to a first stair 11 farther away from the substrate 20.

Specifically, as shown in FIG. 2 or FIG. 3, the multiple conductive pillars 24 in the conductive pillar structure are located on the multiple first stairs 11 in the first staircase structure 42 in a one-to-one correspondence, and are electrically connected to the multiple first stairs 11 in a one-to-one correspondence. Each conductive pillar 24 extends in the first direction D1, and is configured to transmit an external control signal to a corresponding signal line 10 through each one of the multiple first stairs 11. Because the multiple first stairs 11 in the first staircase structure 42 are arranged in the second direction D2, the multiple conductive pillars 24 in the conductive pillar structure are arranged at intervals in the second direction D2, thereby increasing a distance between adjacent conductive pillars 24 in the second direction D2, lowering a capacitive coupling effect between the adjacent conductive pillars 24, and further improving the electrical performance of the semiconductor structure. Top surfaces of all conductive pillars 24 in the conductive pillar structure are flush, and both the width of each one of the multiple conductive pillars 24 in the second direction D2 and the width of each one of the multiple conductive pillars 24 in the third direction D3 increase with the height of each one of the multiple conductive pillars 24 in the first direction D1. Impact of the height of each one of the multiple conductive pillars 24 in the first direction D1 and a cross-sectional area of each one of the multiple conductive pillars 24 is balanced, to reduce a difference in RC delay (resistive-capacitive delay) between the conductive pillars 24.

In some embodiments, the multiple conductive pillars 24 may be unevenly arranged at intervals in the second direction D2, and spacings between the multiple adjacent conductive pillars 24 arranged at intervals in the second direction D2 increase or decrease in the second direction D2 in sequence. For example, the spacing between the adjacent conductive pillars 24 may be positively correlated with an overlapping area of the adjacent conductive pillars 24 in the first direction D1, to alleviate a capacitive coupling effect between the adjacent conductive pillars 24. In the second direction D2, the multiple first stairs 11 arranged in the second direction D2 may have sizes increasing or decreasing in sequence.

In some embodiments, each one of the multiple first stairs 11 is partially located on an end face of the corresponding signal line 10 in the third direction D3, and is partially located on a top surface of the corresponding signal line 10 in the first direction D1; or a projection of each one of the multiple first stairs 11 on an end face of the corresponding signal line 10 in the third direction D3 is completely located on the end face of the corresponding signal line 10 in the third direction D3.

In an example, each one of the multiple first stairs 11 is partially located on the end face of the corresponding signal line 10 in the third direction D3, and is partially located on the top surface of the corresponding signal line 10 in the first direction D1, so that each one of the multiple first stairs 11 semi-surrounds the corresponding signal line 10. On one hand, a contact area between each one of the multiple first stairs 11 and the corresponding signal line 10 can be increased, and a stable connection between each one of the multiple first stairs 11 and the corresponding signal line 10 can be ensured while contact resistance between each one of the multiple first stairs 11 and the corresponding signal line 10 is reduced. On the other hand, a process window of each one of the multiple first stairs 11 can be further increased, thereby further reducing process difficulty of the semiconductor structure. In another example, the projection of each one of the multiple first stairs 11 on the end face of the corresponding signal line 10 in the third direction D3 is completely located on the end face of the corresponding signal line 10 in the third direction D3, to further reduce the size of the first staircase structure 42 while ensuring a stable connection between each one of the multiple first stairs 11 and the corresponding signal line 10, helping further miniaturize the size of the semiconductor structure.

In some embodiments, all the first stairs 11 in the first staircase structure 42 extend in the third direction D3, all the first stairs 11 in the first staircase structure 42 are equal in length in the third direction D3, and the multiple first stairs 11 sequentially arranged in the first direction D1 are arranged at intervals in the second direction D2 in the same sequence.

In this specific implementation, each one of the multiple first stairs 11 is disposed at the end portion of the corresponding signal line 10 in the third direction D3, and all the first stairs 11 sequentially arranged in the first direction D1 are arranged at intervals in the second direction D2 in the same sequence, that is, the multiple first stairs 11 in the first staircase structure 42 are arranged at intervals in the first direction D1, and are also arranged at intervals in the second direction D2. All the first stairs 11 in the first staircase structure 42 are sequentially sorted in the first direction D1, all the first stairs 11 in the first staircase structure 42 are sequentially sorted in the second direction D2, and all the first stairs 11 in the first staircase structure 42 are arranged in the first direction D1 in a sequence the same as that in which all the first stairs 11 in the first staircase structure 42 are arranged in the second direction D2. For example, the first staircase structure 42 includes N first stairs 11. The N first stairs 11 are sequentially sorted in the first direction D1 (e.g., a direction in which the substrate 20 points to the stacked structure 40) to form a first stair sequence, the N stairs 11 are sequentially sorted in the second direction D2 to form a second stair sequence, and the first stair sequence is the same as the second stair sequence. A first stair located at an Xth position in the first stair sequence is also located at an Xth position in the second stair sequence. Herein, N is an integer greater than or equal to 3, and X is a positive integer less than or equal to N.

In some embodiments, the multiple first stairs 11 sequentially arranged in the first direction D1 are arranged at intervals in the second direction D2 in the same sequence, so that two first stairs 11 electrically connected to two adjacent signal lines 10 are disposed in a staggered manner in the second direction D2. In this way, a distance, in the second direction D2, between the first stairs 11 electrically connected to the adjacent signal lines 10 is increased, and an overlapping area between the two adjacent first stairs 11 is reduced, thereby lowering a capacitive coupling effect between the two adjacent first stairs 11, implementing a minimum RC delay and maximum capacitance density in the semiconductor structure, and improving the electrical performance of the semiconductor structure.

In an example, in any two of the multiple first stairs 11 adjacent to each other in the second direction D2, a first stair 11 electrically connected to a signal line 10 closer to the substrate 20 is located below a first stair 11 electrically connected to a signal line 10 farther away from the substrate 20, that is, all the first stairs 11 in the first staircase structure 42 are sequentially arranged in the first direction D1 from low to high.

In another example, in any two of the multiple first stairs 11 adjacent to each other in the second direction D2, a first stair 11 electrically connected to a signal line 10 closer to the substrate 20 is located above a first stair 11 electrically connected to a signal line 10 farther away from the substrate 20, that is, all the first stairs 11 in the first staircase structure 42 are sequentially arranged in the first direction D1 from high to low.

In another example, there is a case in which in two of the multiple first stairs 11 adjacent to each other in the second direction D2, a first stair 11 electrically connected to a signal line 10 closer to the substrate 20 is located above a first stair 11 electrically connected to a signal line 10 farther away from the substrate 20; and there is a case in which in two of the multiple first stairs 11 adjacent to each other in the second direction D2, a first stair 11 electrically connected to a signal line 10 closer to the substrate 20 is located below a first stair 11 electrically connected to a signal line 10 farther away from the substrate 20. That is, the multiple first stairs 11 arranged at intervals in the second direction D2 are staggered in height in the first direction D1.

In some embodiments, at least two stacked structures 40 are arranged at intervals in the third direction D3, and two signal line groups 41 are respectively and correspondingly electrically connected to the at least two stacked structures 40.

The two signal line groups 41 are distributed on two opposite sides of the first staircase structure 42 in the third direction D3, one end of a given one of the first stairs 11 in the third direction D3 is electrically connected to one signal line 10 in one signal line group 41, and the other end of the given one of the first stairs 11 in the third direction D3 is electrically connected to one signal line 10 in the other signal line group 41.

For example, as shown in FIG. 4, two stacked structures 40 arranged at intervals in the third direction D3 share one first staircase structure 42, thereby further reducing the projection area of the semiconductor structure, and facilitating further reduction in the size of the semiconductor structure.

In some embodiments, as shown in FIG. 2, the semiconductor structure further includes: an isolation layer, including first isolation layers 22 and second isolation layers 23 that are alternately arranged in the second direction D2, the first isolation layers 22 being located on top surfaces of the first stairs 11, each one of the second isolation layers 23 being located between two first stairs 11 adjacent to each other in the second direction D2, and a bottom surface of a given one of the second isolation layers 23 being lower than a bottom surface of an adjacent first isolation layer 22.

For example, as shown in FIG. 1 and FIG. 2, the semiconductor structure further includes a second staircase structure 21 located on one side of the signal line group 41 in the third direction D3, and the first staircase structure 42 is located on the second staircase structure. The second staircase structure 21 may be made of an oxide material (e.g., silicon dioxide). The second staircase structure 21 includes multiple second stairs 25 arranged in the first direction D1, the first stairs 11 are located on the second stairs 25, and the width of each one of the first stairs 11 in the second direction D2 is less than the width of each one of the second stairs 25 in the second direction D2, to further increase a distance between adjacent first stairs 11 in the second direction D2, and further alleviate a capacitive coupling effect. The second isolation layers 23 are located on top surfaces of the second stairs 25, and in any two of the multiple first stairs 11 adjacent to each other in the second direction D2, each one of the second isolation layers 23 is located in the second direction D2 on a side of a first stair 11 closer to the substrate 20 and the side faces to the other one of the two first stairs 11. The isolation layer is disposed to include the first isolation layers 22 and the second isolation layers 23 that are alternately arranged in the second direction D2, so that on one hand, parasitic capacitance of the isolation layer can be reduced, and on the other hand, adjacent first stairs 11 and adjacent conductive pillars 24 can be better electrically isolated, to reduce signal crosstalk. In an example, each one of the first isolation layers 22 is made of an oxide material (e.g., silicon dioxide), and each one of the second isolation layers 23 is made of a nitride material (e.g., silicon nitride).

In some other embodiments, as shown in FIG. 3, end faces that are of two adjacent first stairs 11 and that face to each other in the second direction D2 are located on the same plane parallel to the first direction D1, and the semiconductor structure further includes: a dielectric layer 30, the dielectric layer 30 continuously covering the multiple first stairs 11 arranged in the second direction D2, to increase the sizes of the first stairs 11 in the second direction D2, so as to increase an etching window for forming the conductive pillars 24, and reduce manufacturing difficulty of the semiconductor structure. In an example, the dielectric layer 30 may be made of a nitride material (e.g., silicon nitride) or an oxide material (e.g., silicon dioxide).

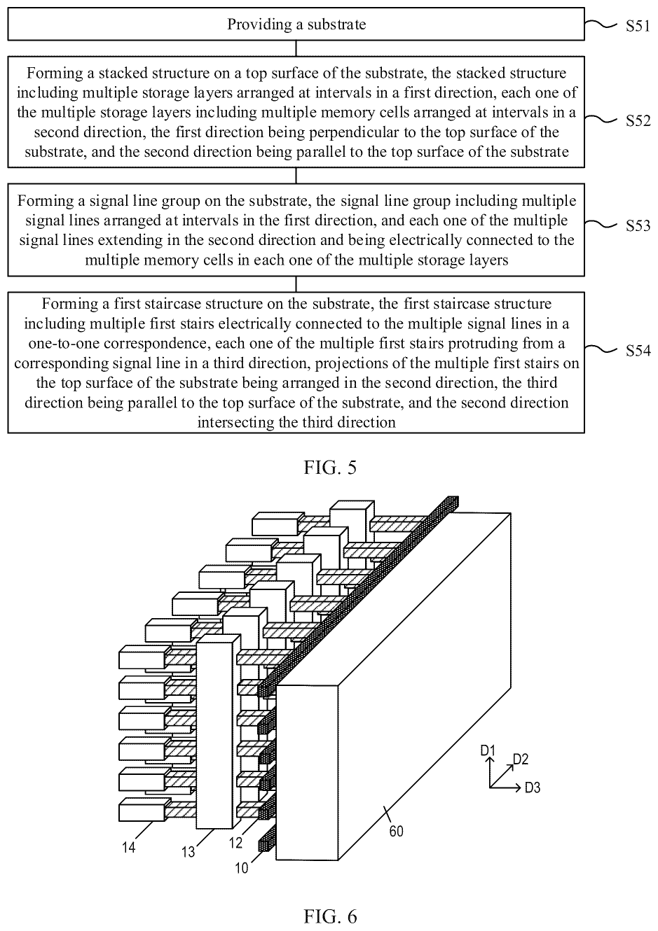

The present disclosure further provides a method for forming a semiconductor structure. FIG. 5 is a flowchart of a method for forming a semiconductor structure. FIG. 6 to FIG. 22 are schematic diagrams of main process structures in a procedure of forming a semiconductor structure according to some embodiments of the present disclosure. For a schematic diagram of a semiconductor structure formed in some embodiments of the present disclosure, reference may be made to FIG. 1 to FIG. 4. As shown in FIG. 1 to FIG. 22, the method for forming a semiconductor structure includes the steps as follows.

In the step of S51, a substrate 20 is provided.

In the step of S52, a stacked structure 40 is formed on a top surface of the substrate 20. The stacked structure 40 includes multiple storage layers 15 arranged at intervals in a first direction D1, and each one of the multiple storage layers 15 includes multiple memory cells 43 arranged at intervals in a second direction D2. The first direction D1 is perpendicular to the top surface of the substrate 20, and the second direction D2 is parallel to the top surface of the substrate 20.

In the step of S53, a signal line group 41 is formed on the substrate 20. The signal line group 41 includes multiple signal lines 10 arranged at intervals in the first direction D1, and each one of the multiple signal lines 10 extends in the second direction D2 and is electrically connected to the multiple memory cells 43 in each one of the multiple storage layers 15.

In the step of S54, a first staircase structure 42 is formed on the substrate 20. The first staircase structure 42 includes multiple first stairs 11 electrically connected to the multiple signal lines 10 in a one-to-one correspondence, each one of the multiple first stairs 11 protrudes from a corresponding signal line 10 in a third direction D3, and projections of the multiple first stairs 11 on the top surface of the substrate 20 are arranged in the second direction D2. The third direction D3 is parallel to the top surface of the substrate 20, and the second direction D2 intersects the third direction D3.

In some embodiments, the step in which a first staircase structure 42 is formed on the substrate 20 includes the steps as follows.

A second staircase structure 21 is formed on the substrate 20. The second staircase structure 21 is located at one side of the signal line group 41 in the third direction D3, the second staircase structure 21 includes multiple second stairs 25 arranged in the first direction D1, and in two second stairs 25 adjacent to each other in the first direction D1, one of the two second stairs 25 closer to the substrate 20 protrudes from the other one of the two second stairs 25 in the second direction D2, as shown in FIG. 7.

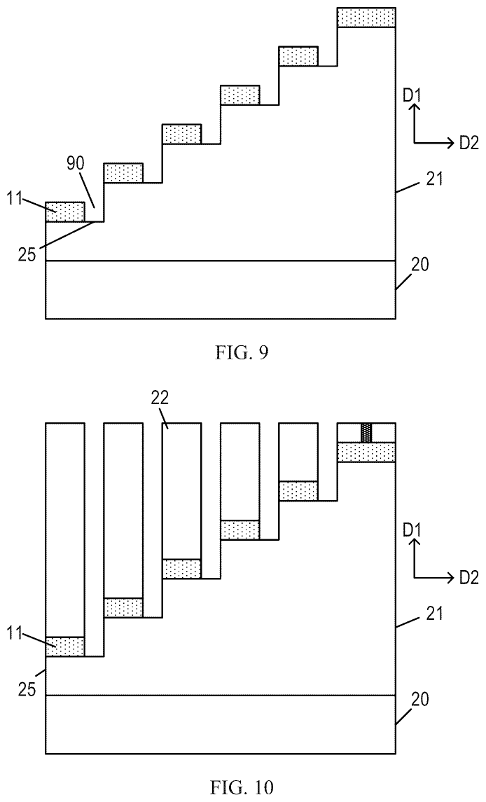

The first staircase structure is formed on the second staircase structure 21. The first staircase structure includes the multiple first stairs 11 electrically connected to the multiple signal lines 10 in a one-to-one correspondence, and the multiple first stairs 11 are located on the multiple second stairs 25 in a one-to-one correspondence, as shown in FIG. 9.

In some embodiments, a top surface of the second staircase structure 21 is located below a top surface of a signal line 10 at the topmost level of the signal line group 41, a top surface of each second stair 25 is flush with or lower than a bottom surface of an adjacent signal line 10, and the step in which the first staircase structure is formed on the second staircase structure 21 includes the steps as follows.

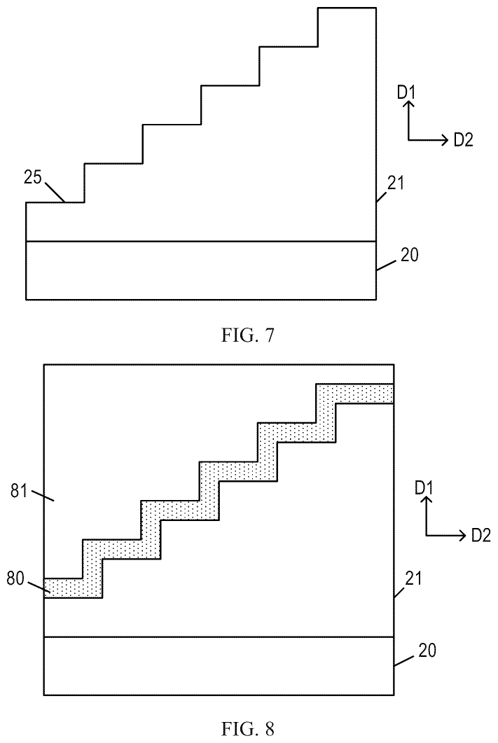

A staircase material is deposited on the second staircase structure 21 to form an initial first staircase structure 80 continuously covering the multiple second stairs 25 in the second staircase structure 21, as shown in FIG. 8. The initial first staircase structure 80 abuts the signal line group.

A part that is of the staircase material and that covers sidewalls of the second stairs 25 is removed, to form the multiple first stairs 11 and first trenches 90 located between two adjacent first stairs 11, as shown in FIG. 9.

In some embodiments, after the multiple first stairs 11 and the first trenches 90 located between two adjacent first stairs 11 are formed, the method further includes the steps as follows.

First isolation layers 22 covering top surfaces of the first stairs 11 are formed, as shown in FIG. 10.

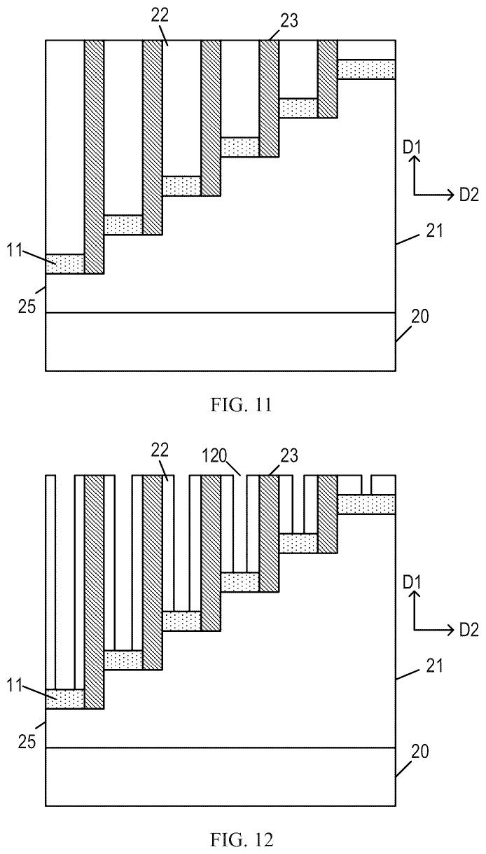

Second isolation layers 23 fully filling the first trenches 90 are formed, as shown in FIG. 11. A top surface of each one of the second isolation layers 23 is flush with a top surface of each one of the first isolation layers 22, and the first isolation layers 22 and the second isolation layers 23 jointly constitute an isolation layer.

In some embodiments, after the second isolation layers 23 fully filling the first trenches 90 are formed, the method further includes the steps as follows.

Multiple vias 120 penetrating through the first isolation layers 22 in the first direction D1 and exposing the first stairs 11 are formed, as shown in FIG. 12. In any two of the multiple vias 120, an inner diameter of a via 120 closer to the substrate 20 may be greater than an inner diameter of a via 120 farther away from the substrate 20.

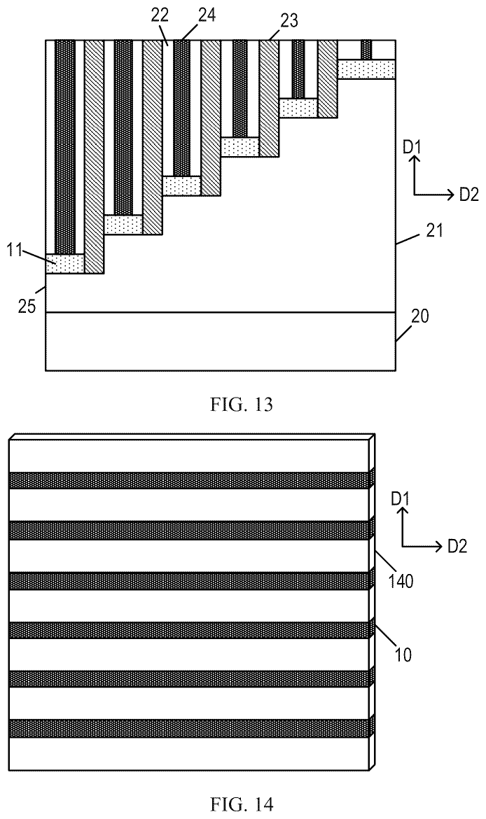

Multiple conductive pillars 24 fully filling the vias 120 are formed, as shown in FIG. 13.

An example in which each one of the multiple signal lines 10 is a bit line in a DRAM is utilized for description. For example, the stacked structure 40 may include multiple memory cells 43 arranged in an array in the first direction D1 and the second direction D2, to form a memory array. Each one of the multiple memory cells 43 includes a transistor and a capacitor 14. The transistor includes an active pillar 12 extending in the third direction D3, the active pillar 12 includes a channel region, and a source region and a drain region distributed on two opposite sides of the channel region in the third direction D3, and the capacitor 14 is electrically connected to the drain region. The semiconductor structure further includes multiple word lines 13 extending in the first direction D1 and being arranged at intervals in the second direction D2, and each word line 13 is electrically connected to multiple memory cells 43 arranged at intervals in the first direction D1, as shown in FIG. 6. The multiple signal lines 10 (that is, bit lines) extend in the second direction D2 and are arranged at intervals in the first direction D1, and each signal line 10 is electrically connected to all memory cells 43 in one storage layer 15. Then, an initial second staircase structure 60 is formed at the end portion of the signal line group 41 in the third direction D3, as shown in FIG. 6. The initial second staircase structure 60 is patterned to form the second staircase structure 21 shown in FIG. 7.

Then, a conductive material such as metal tungsten is deposited on the second staircase structure 21 to form the initial first staircase structure 80 continuously covering the multiple second stairs 25 in the second staircase structure 21, and form a mask layer 81 covering the initial first staircase structure 80, as shown in FIG. 8. The mask layer 81 is patterned to form an etching window partially exposing the initial first staircase structure 80. The initial first staircase structure 80 is etched downward along the etching window to form the multiple first stairs 11 arranged at intervals in the second direction D2 and the first trenches 90 located between adjacent first stairs 11. After the mask layer 81 is removed, the structure shown in FIG. 9 is obtained. Alternatively, the patterned mask layer 81 may be retained as the first isolation layers 22. After the first isolation layers 22 covering the first stairs 11 (as shown in FIG. 10) and the second isolation layers 23 filling the first trenches 90 (as shown in FIG. 11) are formed, the first isolation layers 22 are etched to form the vias 120 penetrating through the first isolation layers 22 in the first direction and exposing the first stairs, as shown in FIG. 12. A conductive material such as metal tungsten is filled in the vias 120 to form the conductive pillars 24, as shown in FIG. 13.

In some other embodiments, a top surface of the second staircase structure 21 is located above a top surface of a signal line 10 at the topmost level of the signal line group 41, top surfaces of at least some second stairs 25 are flush with or lower than bottom surfaces of adjacent signal lines 10, and the step in which the first staircase structure 42 is formed on the second staircase structure 21 includes the steps as follows.

Sacrificial layers 180 that are located on the multiple second stairs 25 in a one-to-one correspondence and that are independent of each other are formed on the second staircase structure 21. Each one of the multiple sacrificial layers 180 abuts a corresponding adjacent signal line 10, as shown in FIG. 18.

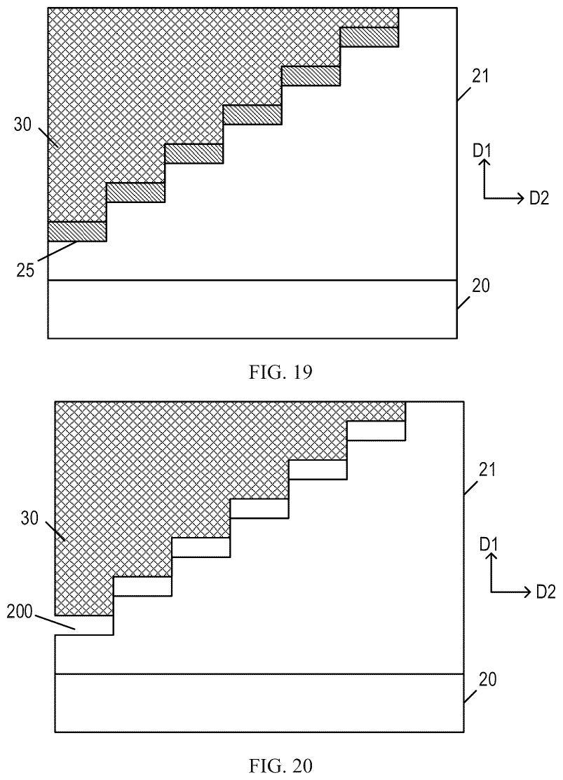

A dielectric layer 30 continuously covering the multiple sacrificial layers 180 and the multiple second stairs 25 is formed, as shown in FIG. 19.

The sacrificial layers 180 are removed to form second trenches 200 between the second stair 25 and the dielectric layer 30, as shown in FIG. 20.

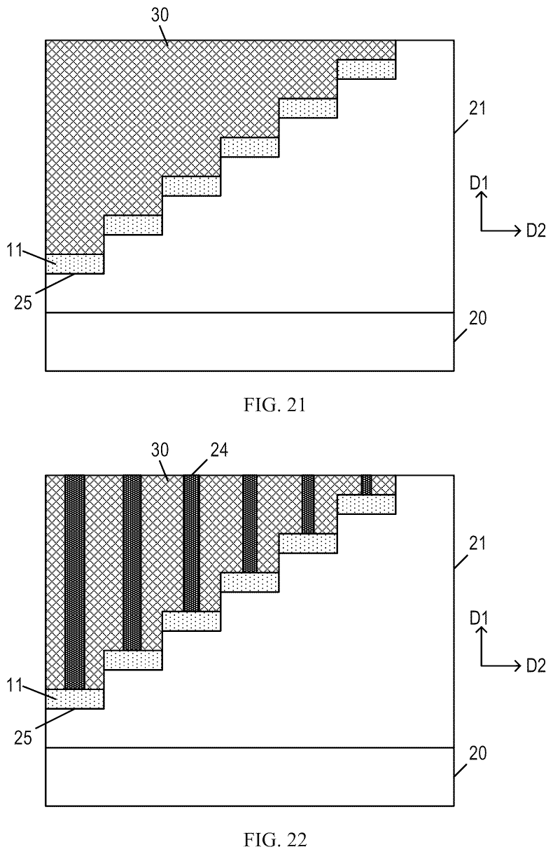

The first stairs 11 located on the second stairs 25 are formed in the second trenches 200, as shown in FIG. 21.

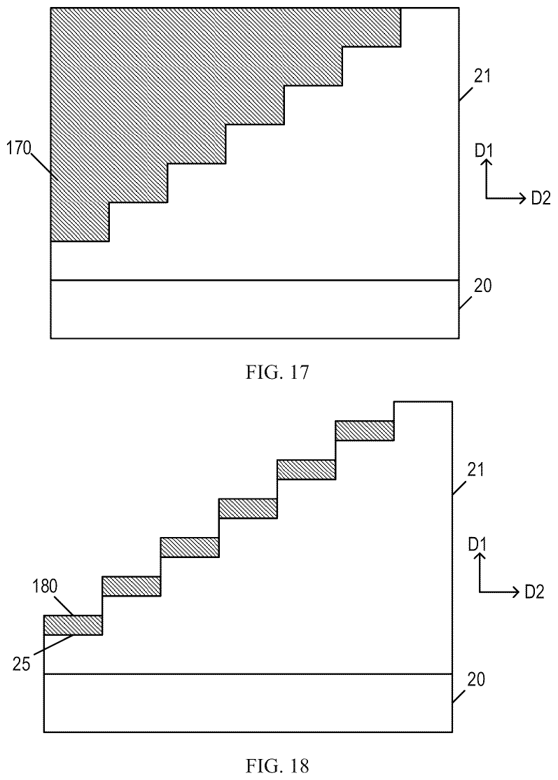

In some embodiments, the step in which sacrificial layers 180 that are located on the multiple second stairs 25 in a one-to-one correspondence and that are independent of each other are formed on the second staircase structure 21 includes the steps as follows. An initial sacrificial layer 170 continuously covering the multiple second stairs 25 in the second staircase structure 21 is formed, as shown in FIG. 16 and FIG. 17. A part that is of the initial sacrificial layer 170 and that covers sidewalls of the second stairs 25 and a part of the initial sacrificial layer 170 located on the second stairs 25 are removed, and a part of the initial sacrificial layer 170 on the second stairs 25 is retained as the sacrificial layers 180. Projections of the sacrificial layers 180 on the substrate are continuously arranged in the second direction D2, as shown in FIG. 18.

In some embodiments, a mask layer may be sequentially formed in the initial sacrificial layer 170, and the mask layer exposes a surface of the initial sacrificial layer 170 above different second stairs 25. Various regions of the initial sacrificial layer 170 are sequentially etched, and a part with a preset height of the initial sacrificial layer 170 is retained on each second stair 25 as each one of the sacrificial layers 180.

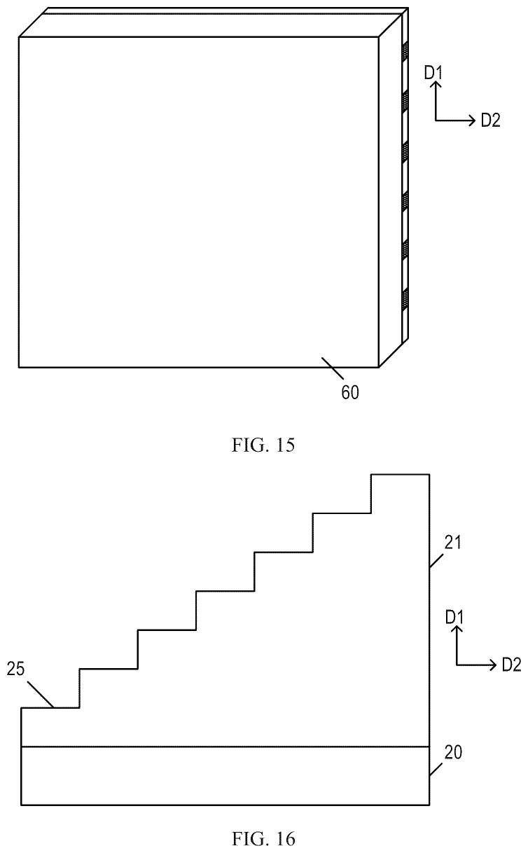

An example in which each one of the multiple signal lines 10 is a bit line in a DRAM is utilized for description. For example, after the stacked structure 40 is formed, a signal line 10 and an inter-layer insulation layer 140 that are alternately stacked in the first direction D1 are formed at an end portion of the stacked structure in the third direction D3, as shown in FIG. 14. The multiple signal lines 10 arranged at intervals in the first direction D1 form a signal line group. The inter-layer insulation layer 140 may be made of a nitride material (e.g., silicon nitride), and is configured to electrically isolate adjacent signal lines 10. Then, an initial second staircase structure 60 is formed on a side that is of the signal line group and that faces away from the stacked structure 40, as shown in FIG. 15. The initial second staircase structure 60 is patterned to form the second staircase structure 21 shown in FIG. 16. In an example, the second staircase structure 21 is made of a nitride material (e.g., silicon nitride). Then, the initial sacrificial layer 170 continuously covering the multiple second stairs 25 in the second staircase structure 21 is formed, as shown in FIG. 17. In an example, the initial sacrificial layer 170 is made of an oxide material (e.g., silicon dioxide). The initial sacrificial layer 170 is patterned, and only a part of the initial sacrificial layer 170 located on the second stairs 25 is retained as the sacrificial layers 180, as shown in FIG. 18. The dielectric layer 30 continuously covering the multiple sacrificial layers 180 and the multiple second stairs 25 is formed, as shown in FIG. 19. Then, the sacrificial layers 180 are removed through a selective etching process to form the second trenches 200 shown in FIG. 20 between the second stairs 25 and the dielectric layer 30. A conductive material such as metal tungsten is filled in the second trenches 200 to form the first stairs 11 shown in FIG. 21. Projections of the first stairs 11 on the substrate are continuously arranged in the second direction D2. Then, conductive pillars 24 penetrating through the dielectric layer 30 in the first direction D1 and being electrically connected to the first stairs 11 are formed, as shown in FIG. 22. The sizes of the sacrificial layers 180 are adjusted, so that the sizes of the first stairs 11 (e.g., the thicknesses of the first stairs 11 in the first direction D1 and the widths of the first stairs 11 in the second direction D2) can be flexibly adjusted, thereby further improving process flexibility of the semiconductor structure.

In some embodiments, at least two stacked structures 40 are arranged at intervals in the third direction D3, and two signal line groups 41 are respectively and correspondingly electrically connected to the at least two stacked structures 40; and the step in which a first staircase structure 42 is formed on the substrate 20 includes the step as follows.

The first staircase structure 42 located between the two signal line groups 41 adjacent to each other in the third direction D3 is formed on the substrate 20. One end of a given one of the first stairs 11 in the third direction D3 is electrically connected to one signal line 10 in one signal line group 41, and the other end of the given one of the first stairs 11 in the third direction D3 is electrically connected to one signal line 10 in the other signal line group 41, as shown in FIG. 4.

According to the semiconductor structure and the method for forming the same provided in some embodiments of the present disclosure, the first staircase structure is disposed at the end portion of the signal line group in the third direction, and the multiple first stairs in the first staircase structure protrude from the signal lines in a one-to-one correspondence in the third direction and are electrically connected to the signal lines. In this way, not only a projection area of the entire first staircase structure on the top surface of the substrate is reduced, but also a distance between two first stairs electrically connected to two adjacent signal lines can be increased, thereby lowering a capacitive coupling effect inside the semiconductor structure, and improving electrical performance of the semiconductor structure.

The foregoing descriptions are merely example implementations of the present disclosure. It should be noted that a person of ordinary skill in the art may make several improvements or polishing without departing from the principle of the present disclosure and the improvements or polishing shall fall within the protection scope of the present disclosure.

What is claimed is:

1. A semiconductor structure, comprising:
a substrate;
a stacked structure, located on a top surface of the substrate, the stacked structure comprising a plurality of storage layers arranged at intervals in a first direction, each one of the plurality of storage layers comprising a plurality of memory cells arranged at intervals in a second direction, the first direction being perpendicular to the top surface of the substrate, and the second direction being parallel to the top surface of the substrate;
a signal line group, comprising a plurality of signal lines arranged at intervals in the first direction, each one of the plurality of signal lines extending in the second direction and being electrically connected to the plurality of memory cells in each one of the plurality of storage layers; and
a first staircase structure, comprising a plurality of first stairs electrically connected to the plurality of signal lines in a one-to-one correspondence, each one of the plurality of first stairs protruding from a corresponding signal line in a third direction, projections of the plurality of first stairs on the top surface of the substrate being arranged in the second direction, the third direction being parallel to the top surface of the substrate, and the second direction intersecting the third direction.

2. The semiconductor structure according to claim 1, further comprising:
a conductive pillar structure, comprising a plurality of conductive pillars electrically connected to the plurality of first stairs in a one-to-one correspondence, each one of the plurality of conductive pillars extending in the first direction and being located above a corresponding first stair, the plurality of conductive pillars having a same size in the second direction and being evenly arranged at intervals in the second direction, and heights, in the first direction, of the plurality of conductive pillars evenly arranged at intervals in the second direction increasing or decreasing in sequence.

3. The semiconductor structure according to claim 1, further comprising:
a conductive pillar structure, comprising a plurality of conductive pillars electrically connected to the plurality of first stairs in a one-to-one correspondence, each one of the plurality of conductive pillars extending in the first direction and being located above a corresponding first stair, and spacings between a plurality of adjacent conductive pillars arranged at intervals in the second direction increasing or decreasing in the second direction in sequence.

4. The semiconductor structure according to claim 1, further comprising:
a conductive pillar structure, comprising a plurality of conductive pillars electrically connected to the plurality of first stairs in a one-to-one correspondence, each one of the plurality of conductive pillars extending in the first direction and being located above a corresponding first stair, and in any two of the plurality of conductive pillars, a width, in the second direction, of a conductive pillar electrically connected to a first stair closer to the substrate being greater than a width, in the second direction, of a conductive pillar electrically connected to a first stair farther away from the substrate.

5. The semiconductor structure according to claim 1, wherein each one of the plurality of first stairs is partially located on an end face of the corresponding signal line in the third direction, and is partially located on a top surface of the corresponding signal line in the first direction; or
a projection of each one of the plurality of first stairs on an end face of the corresponding signal line in the third direction is completely located on the end face of the corresponding signal line in the third direction.

6. The semiconductor structure according to claim 1, wherein all the first stairs in the first staircase structure extend in the third direction, all the first stairs in the first staircase structure are equal in length in the third direction, and the plurality of first stairs sequentially arranged in the first direction are arranged at intervals in the second direction in a same sequence.

7. The semiconductor structure according to claim 6, wherein in any two of the plurality of first stairs adjacent to each other in the second direction, a first stair electrically connected to a signal line closer to the substrate is located below a first stair electrically connected to a signal line farther away from the substrate.

8. The semiconductor structure according to claim 1, wherein at least two stacked structures are arranged at intervals in the third direction, and two signal line groups are respectively and correspondingly electrically connected to the at least two stacked structures; and
the two signal line groups are distributed on two opposite sides of the first staircase structure in the third direction, one end of a given one of the first stairs in the third direction is electrically connected to one signal line in one signal line group, and the other end of the given one of the first stairs in the third direction is electrically connected to one signal line in the other signal line group.

9. The semiconductor structure according to claim 1, further comprising:
an isolation layer, comprising first isolation layers and second isolation layers that are alternately arranged in the second direction, the first isolation layers being located on top surfaces of the first stairs, each one of the second isolation layers being located between two first stairs adjacent to each other in the second direction, and a bottom surface of a given one of the second isolation layers being lower than a bottom surface of an adjacent first isolation layer.

10. The semiconductor structure according to claim 9, further comprising:
a second staircase structure, located on one side of the signal line group in the third direction, the first staircase structure being located on the second staircase structure, the second staircase structure comprising a plurality of second stairs arranged in the first direction, the first stairs being located on the second stairs, and a width of each one of the first stairs in the second direction being less than a width of each one of the second stairs in the second direction.

11. The semiconductor structure according to claim 10, wherein the second isolation layers are located on top surfaces of the second stairs, and in any two of the plurality of first stairs adjacent to each other in the second direction, each one of the second isolation layers is located in the second direction on a side of a first stair closer to the substrate and the side faces to the other one of the two first stairs.

12. The semiconductor structure according to claim 1, wherein end faces that are of two adjacent first stairs and that face to each other in the second direction are located on a same plane parallel to the first direction, and the semiconductor structure further comprises:
a dielectric layer, the dielectric layer continuously covering the plurality of first stairs arranged in the second direction.

13. A method for forming a semiconductor structure, the method comprising:
providing a substrate;
forming a stacked structure on a top surface of the substrate, the stacked structure comprising a plurality of storage layers arranged at intervals in a first direction, each one of the plurality of storage layers comprising a plurality of memory cells arranged at intervals in a second direction, the first direction being perpendicular to the top surface of the substrate, and the second direction being parallel to the top surface of the substrate;
forming a signal line group on the substrate, the signal line group comprising a plurality of signal lines arranged at intervals in the first direction, and each one of the plurality of signal lines extending in the second direction and being electrically connected to the plurality of memory cells in each one of the plurality of storage layers; and
forming a first staircase structure on the substrate, the first staircase structure comprising a plurality of first stairs electrically connected to the plurality of signal lines in a one-to-one correspondence, each one of the plurality of first stairs protruding from a corresponding signal line in a third direction, projections of the plurality of first stairs on the top surface of the substrate being arranged in the second direction, the third direction being parallel to the top surface of the substrate, and the second direction intersecting the third direction.

14. The method for forming a semiconductor structure according to claim 13, wherein forming a first staircase structure on the substrate comprises:
forming a second staircase structure on the substrate, the second staircase structure being located at one side of the signal line group in the third direction, the second staircase structure comprising a plurality of second stairs arranged in the first direction, and in two second stairs adjacent to each other in the first direction, one of the two second stairs closer to the substrate protruding from the other one of the two second stairs in the second direction; and
forming the first staircase structure on the second staircase structure, the plurality of first stairs being located on the plurality of second stairs in a one-to-one correspondence.

15. The method for forming a semiconductor structure according to claim 14, wherein a top surface of the second staircase structure is located below a top surface of a signal line at a topmost level of the signal line group, a top surface of each second stair is flush with or lower than a bottom surface of an adjacent signal line, and forming the first staircase structure on the second staircase structure comprises:
depositing a staircase material on the second staircase structure to form an initial first staircase structure continuously covering the plurality of second stairs in the second staircase structure, the initial first staircase structure abutting the signal line group; and
removing a part that is of the staircase material and that covers sidewalls of the second stairs, to form the plurality of first stairs and first trenches located between two adjacent first stairs.

16. The method for forming a semiconductor structure according to claim 15, wherein after the forming the plurality of first stairs and first trenches located between two adjacent first stairs, the method further comprises:
forming first isolation layers covering top surfaces of the first stairs; and
forming second isolation layers fully filling the first trenches, a top surface of each one of the second isolation layers being flush with a top surface of each one of the first isolation layers, and the first isolation layers and the second isolation layers jointly constituting an isolation layer.

17. The method for forming a semiconductor structure according to claim 16, wherein after the forming second isolation layers fully filling the first trenches, the method further comprises:
forming a plurality of vias penetrating through the first isolation layers in the first direction and exposing the first stairs, in any two of the plurality of vias, an inner diameter of a via closer to the substrate being greater than an inner diameter of a via farther away from the substrate; and
forming a plurality of conductive pillars fully filling the vias.

18. The method for forming a semiconductor structure according to claim 14, wherein a top surface of the second staircase structure is located above a top surface of a signal line at a topmost level of the signal line group, top surfaces of at least some second stairs are flush with or lower than bottom surfaces of adjacent signal lines, and forming the first staircase structure on the second staircase structure comprises:
forming, on the second staircase structure, sacrificial layers that are located on the plurality of second stairs in a one-to-one correspondence and that are independent of each other, each one of the sacrificial layers abutting a corresponding adjacent signal line;
forming a dielectric layer continuously covering a plurality of sacrificial layers and the plurality of second stairs;
removing the sacrificial layers to form second trenches between the second stairs and the dielectric layer; and
forming, in the second trenches, the first stairs located on the second stairs.

19. The method for forming a semiconductor structure according to claim 18, wherein forming, on the second staircase structure, sacrificial layers that are located on the plurality of second stairs in a one-to-one correspondence and that are independent of each other comprises:
forming an initial sacrificial layer continuously covering the plurality of second stairs in the second staircase structure; and
removing a part that is of the initial sacrificial layer and that covers sidewalls of the second stairs and a part of the initial sacrificial layer located on the second stairs, and retaining a part of the initial sacrificial layer on the second stairs as the sacrificial layers.

20. The method for forming a semiconductor structure according to claim 13, wherein at least two stacked structures are arranged at intervals in the third direction, and two signal line groups are respectively and correspondingly electrically connected to the at least two stacked structures; and forming a first staircase structure on the substrate comprises:
forming, on the substrate, the first staircase structure located between the two signal line groups adjacent to each other in the third direction, one end of a given one of the first stairs in the third direction being electrically connected to one signal line in one signal line group, and the other end of the given one of the first stairs in the third direction being electrically connected to one signal line in the other signal line group.
